(19) United States
(12) Patent Application Publication
(10) Pub. No.: US 2025/0220803 A1
(43) Pub. Date: Jul. 3, 2025

(54) DISPLAY PANEL, BONDING DEVICE THEREOF, AND DISPLAY DEVICE

(71) Applicant: WUHAN CHINA STAR OPTOELECTRONICS TECHNOLOGY CO., LTD., Wuhan, Hubei (CN)

(72) Inventor: Shuya DONG, Wuhan (CN)

(21) Appl. No.: 17/799,660

(22) PCT Filed: Jul. 29, 2022
(86) PCT No.: PCT/CN2022/109115

§ 371 Date: Mar. 10, 2025

(30) Foreign Application Priority Data
Jul. 11, 2022 (CN) 202210811850.4

(51) Int. Cl. H05K 1/02; H05K 1/18

(52) U.S. Cl. CPC H05K 1/0213; H05K 1/189; H05K 2201/09409; H05K 2201/10128

(57) ABSTRACT

The present disclosure discloses a display panel, a bonding device thereof and a display device. The display panel includes a display area, a first terminal area, a second terminal area, and a wiring area. The display area and the second terminal area are located on both sides of the first terminal area in a first direction, and a length of the wiring area in the first direction is 50 μm-200 μm. Alternatively, two second terminal areas are located on both sides of the first terminal area in a second direction, and lengths of two wiring areas in the second direction are both 50 μm-400 μm.

### TECHNICAL FIELD

The present disclosure relates to a display field, and more particularly, to a display panel, a bonding device thereof and a display device.

### BACKGROUND

Narrow bezel technology has always been the focus of research in the display field due to its higher display-to-body ratio (or proportion of display) and better visual experience.

A bonding process of the display panel includes an integrated circuit chip (IC) bonding process and a flexible printed circuit (FPC) bonding process. In the related art, the IC bonding process and the FPC bonding process are separately and sequentially performed. In the IC bonding process, an ACF attachment operation, an alignment operation, and a bonding operation need to be performed once respectively. In the FPC bonding process, an ACF attachment operation, an alignment operation, and a bonding operation need to be performed once again respectively. In order to guarantee bonding effects of the two bonding operations, sufficient error margins need to be reserved for the IC bonding process and the FPC bonding process, which results in a large interval between an IC and an FPC and affects a narrow bezel effect of the display panel.

### SUMMARY

### Technical Problems

The present disclosure provides a display panel in which a bezel of the display panel is reduced by reducing the interval between an IC terminal area and an FPC terminal area.

### Technical Solutions for the Problems

### Technical Solutions

The present disclosure provides a display panel including a display area and a terminal area, wherein the terminal area includes a first terminal area, a second terminal area, and a wiring area, and the wiring area is located between the first terminal area and the second terminal area; and
wherein the display area, the first terminal area, the wiring area, and the second terminal area are arranged sequentially in a first direction, and a length of the wiring area in the first direction is 50 μm-200 μm; or
wherein the number of the second terminal areas and the number of the wiring areas are both two, the display area and the first terminal area are arranged in the first direction, one of the second terminal areas, one of the wiring areas, the first terminal area, the other of the wiring areas, the other of the second terminal areas are sequentially arranged in a second direction, and lengths of both of the wiring areas in the second direction are both 50 μm-400 μm.

Alternatively, in some embodiments of the present disclosure, the display area, the first terminal area, the wiring area, and the second terminal area are sequentially arranged in the first direction, and the length of the wiring area in the first direction is 100 μm-200 μm.

Alternatively, in some embodiments of the present disclosure, the lengths of both of the wiring areas in the second direction are both 100 μm-400 μm.

Alternatively, in some embodiments of the present disclosure, the first direction is perpendicular to the second direction

Alternatively, in some embodiments of the present disclosure, both of the wiring areas have a same length in the second direction, and/or both of the wiring areas have a same length in the first direction.

Alternatively, in some embodiments of the present disclosure, both of the second terminal areas are symmetrically arranged on opposite sides of the first terminal area, and both of the wiring areas are symmetrically arranged on the opposite sides of the first terminal area.

The present disclosure provides a bonding device for bonding the display panel according to the present disclosure, the bonding device including:
a common base;
a first pressure head and a second pressure head, wherein the first pressure head and the second pressure head are located on a same side of the common base and respectively connected to the common base, and wherein a distance between the first pressure head and the second pressure head is in the range of 50 μm-400 μm.

Alternatively, in some embodiments of the present disclosure, the number of the second pressure head is one, and the distance between the first pressure head and the second pressure head is in a range of 50 μm-200 μm.

Alternatively, in some embodiments of the present disclosure, the distance between the first pressure head and the second pressure head is in a range of 100 μm-200 μm.

Alternatively, in some embodiments of the present disclosure, the number of the second pressure heads is two, and distances between both of the second pressure heads and the first pressure head are both in a range of 50 μm-400 μm.

Alternatively, in some embodiments of the present disclosure, the distances between both of the second pressure heads and the first pressure head are both in a range of 100 μm-400 μm.

Alternatively, in some embodiments of the present disclosure, the first pressure head is movably connected to the common base, and/or the second pressure head is movably connected with the common base.

Alternatively, in some embodiments of the present disclosure, the first pressure head is moved along a direction toward or away from the common base, and/or the first pressure head is moved along a direction toward or away from the second pressure head; and/or
the second pressure head is moved along the direction toward or away from the common base, and/or the second pressure head is moved along the direction toward or away from the first pressure head.

Alternatively, in some embodiments of the present disclosure, the bonding device further includes a first control system and a second control system, the first control system includes a first temperature control system, a first pressure control system, a first temperature sensor, and a first pressure sensor, and the second control system includes a second temperature control system, a second pressure control system, a second temperature sensor, and a second pressure sensor.

Meanwhile, the present disclosure further provides a display device including a flexible circuit board, an integrated circuit chip, and a display panel, wherein the display panel includes a display area and a terminal area, the terminal area includes a first terminal area, a second terminal area, and a wiring area, and the wiring area is located between the first terminal area and the second terminal area; and wherein the display area, the first terminal area, the wiring area, and the second terminal area are arranged sequentially in a first direction, and a length of the wiring area in the first direction is 50 μm-200 μm; or
wherein the number of the second terminal areas and the number of the wiring areas are both two, the display area and the first terminal area are arranged in the first direction, one of the second terminal areas, one of the wiring areas, the first terminal area, the other of the wiring areas, the other of the second terminal areas are sequentially arranged in a second direction, and lengths of both of the wiring areas in the second direction are both 50 μm-400 μm.

Alternatively, in some embodiments of the present disclosure, the display area, the first terminal area, the wiring area, and the second terminal area are sequentially arranged in the first direction, and the length of the wiring area in the first direction is 100 μm-200 μm.

Alternatively, in some embodiments of the present disclosure, the lengths of both of the wiring areas in the second direction are both 100 μm-400 μm.

Alternatively, in some embodiments of the present disclosure, the first direction is perpendicular to the second direction.

Alternatively, in some embodiments of the present disclosure, both of the wiring areas have a same length in the second direction, and/or both of the wiring areas have a same length in the first direction.

Alternatively, in some embodiments of the present disclosure, both of the second terminal areas are symmetrically arranged on opposite sides of the first terminal area, and both of the wiring areas are symmetrically arranged on the opposite sides of the first terminal area.

### Beneficial Effects of the Invention

### Beneficial Effects

The present disclosure provides a display panel, a bonding device thereof and a display device, by reducing a distance between the first terminal area and the second terminal area, a wiring length in a wiring area is reduced, thereby reducing a width of the wiring area in a first direction and facilitating the realization of a narrow bezel of the display panel.

### BRIEF DESCRIPTION OF THE DRAWINGS

### Drawing Illustrations

Technical solutions and other beneficial effects of the present disclosure will be apparent from the following detailed description of specific embodiments thereof in conjunction with the accompanying drawings.

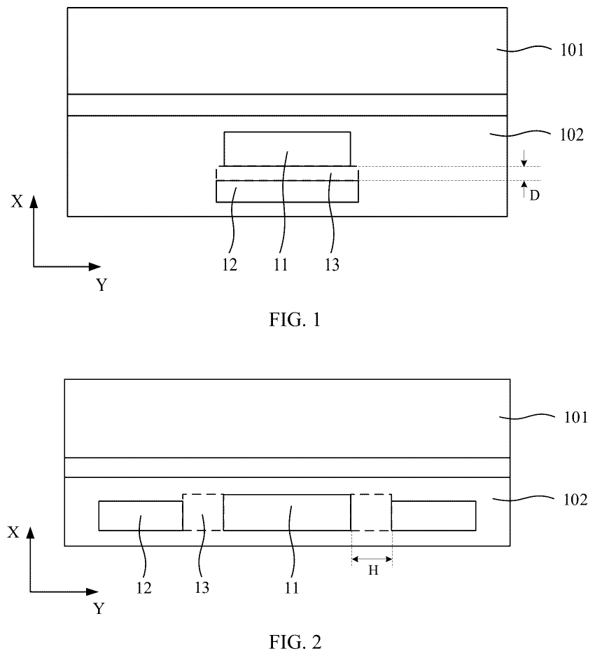

FIG. 1 is a first structural schematic view of a display panel according to an embodiment of the present disclosure;

FIG. 2 is a second structural schematic view of a display panel according to an embodiment of the present disclosure;

FIG. 3 is a bonding structural schematic view of a first display panel and a first bonding device according to an embodiment of the present disclosure;

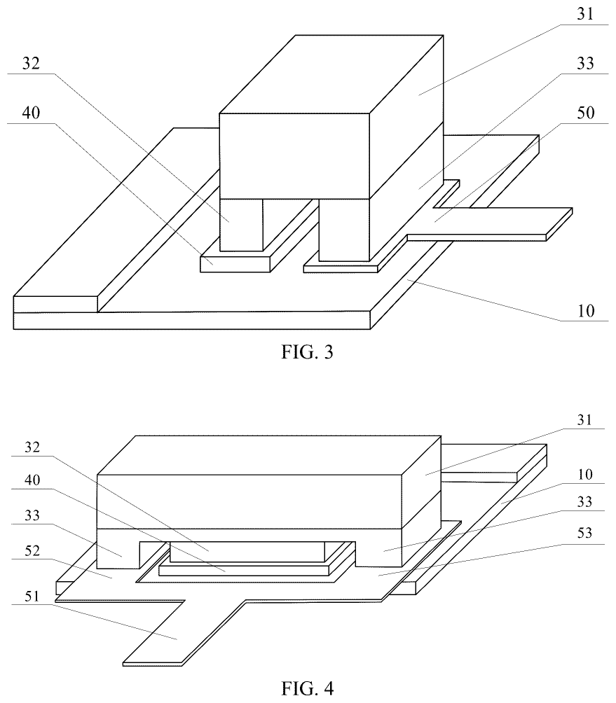

FIG. 4 is a bonding structural schematic view of a second display panel and a second bonding device according to an embodiment of the present disclosure; and

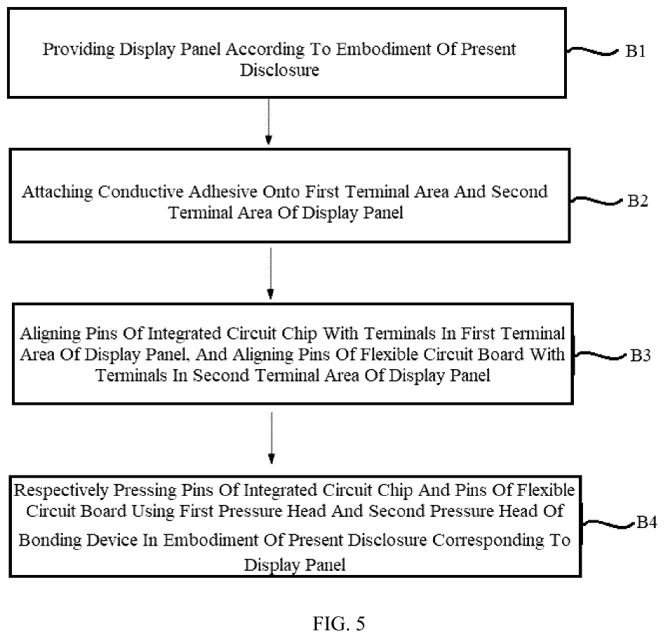

FIG. 5 is a flowchart of a bonding method of a display panel according to an embodiment of the present disclosure.

### EMBODIMENTS OF THE PRESENT INVENTION

### Detailed Description

For a current display panel, a width of a wiring area between an IC terminal and an FPC terminal is too large due to two bonding processes, thereby causing a wider lower bezel of the display panel. The present disclosure provides a display panel, a bonding device and a bonding method thereof to solve the above problem.

In a first embodiment, referring to FIG. 1, FIG. 1 shows a first structural schematic view of a display panel according to an embodiment of the present disclosure. A display panel 10 according to an embodiment of the present disclosure includes a display area 101 and a terminal area 102. The terminal area 102 includes a first terminal area 11, a second terminal area 12, and a wiring area 13. The display area 101, the first terminal area 11, the wiring area 13, and the second terminal area 12 are sequentially arranged in a first direction X. The wiring area 13 is located between the first terminal area 11 and the second terminal area 12, and connects to the first terminal area 11 and the second terminal area 12. A length D of the wiring area 13 in the first direction X is 50 μm-200 μm. Preferably, the length D is 100 μm-200 μm.

Specifically, in the second terminal area 12, the display panel includes an FPC terminal. In the first terminal area 11, the display panel includes an IC terminal electrically connected to the FPC terminal. In the wiring area 13, the display panel includes a terminal wiring that connects the FPC terminal and the IC terminal. The length of the wiring area 13 in the first direction X affects a length of the terminal area 102 in the first direction X, thereby affecting the bezel size of the display panel. In the present embodiment, by reducing a distance between the second terminal area 12 and the first terminal area 11, the length of the terminal wiring is decreased, and the length of the wiring area 13 in the first direction X is reduced, thereby reducing the width of the terminal area 102 and facilitating the realization of a narrow bezel of the display panel.

In a second embodiment, referring to FIG. 2, FIG. 2 shows a second structural schematic view of a display panel according to an embodiment of the present disclosure. A display panel according to an embodiment of the present disclosure includes a display area 101 and a terminal area 102. The terminal area 102 includes a first terminal area 11, two second terminal areas 12, and two wiring areas 13. The display area 101 and the first terminal area 11 are sequentially arranged in the first direction X. One of the second terminal areas 12, one of the wiring areas 13, the first terminal area 11, the other of the wiring areas 13, and the other of the second terminal areas 12 are sequentially arranged in a second direction Y. Each of the wiring areas 13 connects the first terminal area 11 and one of the second terminal areas 12 adjacent to the said wiring area 13. Lengths H of the wiring areas 13 in the second direction Y are both 50 μm-400 μm. Preferably, the lengths H are both 100 μm-400 μm. The first direction X and the second direction Y are perpendicular to each other.

Specifically, in each of the second terminal areas 12, the display panel includes an FPC terminal. In the first terminal area 11, the display panel includes an IC terminal electrically connected to the FPC terminal. In each of the wiring areas 13, the display panel includes a terminal wiring that connects the FPC terminal and the IC terminal in adjacent areas.

In the present embodiment, by reducing distances between the second terminal areas 12 and the first terminal area 11, a length of the terminal wiring in each of the wiring areas 13 is decreased, a width of the terminal wiring is reduced while the terminal wiring is guaranteed to have a predetermined resistance, so that a width of each of the wiring areas 13 is reduced, that is, a length of each of the wiring areas 13 in the first direction X is reduced. Therefore, a length of the terminal area 102 in the first direction X is reduced, thereby facilitating the realization of a narrow bezel of the display panel. Compared with the terminal area in the related art, the length of the terminal area 102 of the display panel in the first direction X is reduced by 50 μm-200 μm in the present embodiment.

Further, in a first implementation, the two wiring areas 13 have the same length in the first direction X, but have different lengths in the second direction Y. In a second implementation, the two wiring areas 13 have different lengths in the first direction X, but have the same length in the second direction Y. In a third implementation, the two wiring areas 13 have the same length in the first direction X, and have the same length in the second direction Y. The third implementation is preferred.

Further, the two second terminal areas 12 are symmetrically arranged on both sides of the first terminal area 11, and the two wiring areas 13 are symmetrically arranged on the both sides of the first terminal area 11.

In an embodiment of the present disclosure, a bonding device for bonding the display panel according to an embodiment of the present disclosure is further provided. Referring to FIGS. 3 and 4, FIG. 3 illustrates a bonding structural schematic view of a first display panel and a first bonding device according to an embodiment of the present disclosure, and FIG. 4 illustrates a bonding structural schematic view of a second display panel and a second bonding device according to an embodiment of the present disclosure. The bonding device includes:
a common base 31;
a first pressure head 32 and a second pressure head 33, wherein the first pressure head 32 and the second pressure head 33 are located on the same side of the common base 31 and respectively connected to the common base 31, and wherein a distance between the first pressure head 32 and the second pressure head 33 is in the range of 50 μm-400 μm.

According to an embodiment of the present disclosure, the first pressure head 32 and the second pressure head 33 are respectively connected to the common base 31, so that a bonding step for an IC chip and a bonding step for an FPC circuit board of the display panel may be performed simultaneously in a one-time bonding operation. An error margin between the IC terminal area and the FPC terminal area required for the two bonding steps in the related art is eliminated. A distance between the IC terminal area and the FPC terminal area is reduced. The length of the terminal wiring is reduced. The width of the wiring area is reduced, thereby facilitating the realization of the narrow bezel of the display panel.

In the first embodiment, referring to FIG. 3, the bonding device is used for bonding the display panel according to the first embodiment. In the bonding device, the number of the second pressure head 33 and the number of the first pressure head 32 are both one, and the distance between the first pressure heads 32 and the second pressure heads 33 is in the range of 50 μm-200 μm. In one implementation, the first pressure head 32 is movably connected to the common base 31. The first pressure head 32 may be moved along a direction toward or away from the common base 31, to adjust a protrusion length of the first pressure head 32, thereby adjusting a pressure applied by the first pressure head 32. The first pressure head 32 may also be moved along a direction toward or away from the second pressure head 33, to adjust the distance between the first pressure head 32 and the second pressure head 33. In another implementation, the second pressure head 33 is movably connected to the common base 31. The second pressure head 33 may be moved along the direction toward or away from the common base 31, to adjust a protrusion length of the second pressure head 33, thereby adjusting a pressure applied by the second pressure head 33. The second pressure head 33 may be moved along a direction toward or away from the first pressure head 32, to adjust the distance between the first pressure head 32 and the second pressure head 33. In yet another implementation, the first pressure head 32 is movably connected to the common base 31, and the second pressure head 33 is movably connected to the common base 31. The first pressure head 32 and the second pressure head 33 may be respectively moved along directions toward or away from the common base 31. The first pressure head 32 and the second pressure head 33 may be respectively moved along directions toward and away from the first pressure head 32. Therefore, the distance between the first pressure head 32 and the second pressure head 33 is adjusted.

In the second embodiment, referring to FIG. 4, the bonding device is used for bonding the display panel according to the second embodiment. In the bonding device, the number of the first pressure head is one, the number of the second pressure heads 33 is two. The two second pressure heads 33 are respectively located on opposite sides of the first pressure heads 32. The distances between the second pressure heads 33 and the first pressure head 32 are in the range of 50 μm-400 μm. Similarly, in one implementation, the first pressure head 32 is movably connected to the common base 31. The first pressure head 32 may be moved along the direction towards or away from the common base 31. The first pressure head 32 may also be moved along the direction towards or away from the second pressure heads 33. In another implementation, the second pressure heads 33 are movably connected to the common base 31. The second pressure heads 33 may be moved along the direction towards or away from the common base 31. The second pressure heads 33 may also be moved along the direction towards or away from the first pressure head 32, respectively. In yet another implementation, the first pressure head 32 is movably connected to the common base 31 and the second pressure heads 33 are movably connected to the common base 31.

Further, the bonding device further includes a first control system and a second control system. The first control system includes a first temperature control system, a first pressure control system, a first temperature sensor, and a first pressure sensor. The first temperature sensor is configured to monitor a temperature of the first pressure head 32. The first temperature control system is configured to control the temperature of the first pressure head 32. The temperature of the first pressure head 32 is adjusted according to a real-time temperature of the first pressure head 32 monitored by the first temperature sensor. The first pressure sensor is configured to monitor a pressure of the first pressure head 32. The first pressure control system is configured to control the pressure of the first pressure head 32. According to a real-time pressure of the first pressure head 32 monitored by the first pressure sensor, the first pressure head 32 is adjusted and the first pressure head 32 is controlled to move along the direction toward or away from the common base 31. The second control system includes a second temperature control system, a second pressure control system, a second temperature sensor, and a second pressure sensor. Similarly, the second temperature sensor is configured to monitor a temperature of the second pressure head 33. The second temperature control system is configured to control the temperature of the second pressure head 33. The temperature of the second pressure head 33 is adjusted according to a real-time temperature of the second pressure head 33 monitored by the second temperature sensor. The second pressure sensor is configured to monitor a pressure of the second pressure head 33. The second pressure control system is configured to control the pressure of the second pressure head 33. According to a real-time pressure of the second pressure head 33 monitored by the second pressure sensor, the second pressure head 33 is adjusted, and the second pressure head 33 is controlled to move along the direction toward or away from the common base 31. When the number of the second pressure heads 33 is two, the number of the second control systems is two, and the second control system respectively controls the two second pressure heads.

Accordingly, in an embodiment of the present disclosure, a bonding method for the display panel is further provided. The display panel according to an embodiment of the present disclosure corresponding to the bonding device according to an embodiment of the present disclosure is bonded by using the bonding device. Referring to FIG. 5, the bonding method includes:
Step B1: providing a display panel according to an embodiment of the present disclosure;
Step B2: attaching a conductive adhesive onto a first terminal area and a second terminal area of the display panel;
Step B3: aligning pins of an integrated circuit chip with terminals in the first terminal area of the display panel, and aligning pins of a flexible circuit board with terminals in the second terminal area of the display panel;
Step B4: respectively pressing the pins of the integrated circuit chip and the pins of the flexible circuit board by using a first pressure head and a second pressure head of the bonding device in an embodiment of the present disclosure corresponding to the display panel.

According to the present embodiment, the bonding of the IC chip and the FPC circuit board to the display panel is performed by one conductive adhesive attaching-terminal alignment-press bonding operation. The error margin between the IC terminal area and the FPC terminal area required for the two bonding steps in the related art is eliminated. The distance between the IC terminal area and the FPC terminal area is reduced. The length of the terminal wiring is reduced. The width of the wiring area is reduced, thereby facilitating the realization of the narrow bezel of the display panel. Meanwhile, the processing time and the cost may be reduced and the production yield may be improved by the one-time bonding compared with the two-time bonding.

Specifically, in the first embodiment, as shown in FIG. 3, the display panel is the display panel according to the first embodiment, and the bonding device is the bonding device according to the first embodiment. The integrated circuit chip 40 is pressed to the first terminal area of the display panel by using the first pressing head 32 of the bonding device, and a flexible circuit board 50 is pressed to the second terminal area of the display panel by using the second pressing head 33.

In a second embodiment, as shown in FIG. 3, the flexible circuit board includes a main body section 51, a first connection section 52 and a second connection section 53 on both sides of the main body section. The integrated circuit chip 40 is pressed to the first terminal area of the display panel by using the first pressure head 32 of the bonding device, and the first connection section 52 and the second connection section 53 are pressed to two second terminal areas of the display panel by using the two second pressure heads 33, respectively.

Meanwhile, in an embodiment of the present disclosure, a display device is further provided. The display device includes a flexible circuit board, an integrated circuit chip, and a display panel according to an embodiment of the present disclosure. The flexible circuit board is bonded to the first terminal area of the display panel, and the integrated circuit chip is bonded to the second terminal area of the display panel. Since the display device includes the display panel according to an embodiment of the present disclosure, the display device has the same technical features and beneficial effects as the display panel according to the embodiment of the present disclosure, and the details may be described with reference to the above-described embodiments, and are not described herein.

In sum, in embodiments of the present disclosure, a display panel, a bonding device thereof, and a display device are provided. By reducing the distance between the IC terminal area and the FPC terminal area of the display panel, and disposing the first pressure head and the second pressure head of the bonding device on the same side of the common base and to be respectively connected to the common base, a bonding step for an IC chip and a bonding step for an FPC circuit board of the display panel may be performed simultaneously in a one-time bonding operation. An error margin between the IC terminal area and the FPC terminal area required for the two bonding steps in the related art is eliminated. A distance between the IC terminal area and the FPC terminal area is reduced. The length of the terminal wiring is reduced. The width of the wiring area is reduced, thereby facilitating the realization of the narrow bezel of the display panel. Meanwhile, the processing time and the cost may be reduced and the production yield may be improved by the one-time bonding compared with the two-time bonding.

A display panel, a bonding device thereof, and a display device according to an embodiment of the present disclosure has been described in detail above. The principles and implementations of the present disclosure are described herein by referring to specific examples. The description of the above embodiments is merely provided to assist in understanding a method of the present disclosure and a core idea thereof. At the same time, variations in the detailed description and scope of application will occur to those skilled in the art in accordance with the teachings of the present disclosure. In light of the foregoing, the description in the present specification is not to be construed as limiting the present application.

What is claimed is:

1. A display panel comprising a display area and a terminal area, wherein the terminal area comprises a first terminal area, a second terminal area, and a wiring area, and the wiring area is located between the first terminal area and the second terminal area; and
wherein the display area, the first terminal area, the wiring area, and the second terminal area are arranged sequentially in a first direction, and a length of the wiring area in the first direction is 50 μm-200 μm; or
wherein the number of the second terminal areas and the number of the wiring areas are both two, the display area and the first terminal area are arranged in the first direction, one of the second terminal areas, one of the wiring areas, the first terminal area, the other of the wiring areas, the other of the second terminal areas are sequentially arranged in a second direction, and lengths of both of the wiring areas in the second direction are both 50 μm-400 μm.

2. The display panel according to claim 1, wherein the display area, the first terminal area, the wiring area, and the second terminal area are sequentially arranged in the first direction, and the length of the wiring area in the first direction is 100 μm-200 μm.

3. The display panel according to claim 1, wherein the lengths of both of the wiring areas in the second direction are both 100 μm-400 μm.

4. The display panel according to claim 1, wherein the first direction is perpendicular to the second direction.

5. The display panel according to claim 1, wherein both of the wiring areas have a same length in the second direction, and/or both of the wiring areas have a same length in the first direction.

6. The display panel according to claim 5, wherein both of the second terminal areas are symmetrically arranged on opposite sides of the first terminal area, and both of the wiring areas are symmetrically arranged on the opposite sides of the first terminal area.

7. A bonding device for bonding the display panel according to claim 1, the bonding device comprising:
a common base;
a first pressure head and a second pressure head, wherein the first pressure head and the second pressure head are located on a same side of the common base and respectively connected to the common base, and wherein a distance between the first pressure head and the second pressure head is in the range of 50 μm-400 μm.

8. The bonding device according to claim 7, wherein the number of the second pressure head is one, and the distance between the first pressure head and the second pressure head is in a range of 50 μm-200 μm.

9. The bonding device according to claim 8, wherein the distance between the first pressure head and the second pressure head is in a range of 100 μm-200 μm.

10. The bonding device according to claim 7, wherein the number of the second pressure heads is two, and distances between both of the second pressure heads and the first pressure head are both in a range of 50 μm-400 μm.

11. The bonding device according to claim 10, wherein the distances between both of the second pressure heads and the first pressure head are both in a range of 100 μm-400 μm.

12. The bonding device according to claim 7, wherein the first pressure head is movably connected to the common base, and/or
the second pressure head is movably connected with the common base.

13. The bonding device according to claim 12, wherein the first pressure head is moved along a direction toward or away from the common base, and/or the first pressure head is moved along a direction toward or away from the second pressure head; and/or
the second pressure head is moved along the direction toward or away from the common base, and/or the second pressure head is moved along a direction toward or away from the first pressure head.

14. The bonding device according to claim 7, wherein the bonding device further comprises a first control system and a second control system, the first control system comprises a first temperature control system, a first pressure control system, a first temperature sensor, and a first pressure sensor, and the second control system comprises a second temperature control system, a second pressure control system, a second temperature sensor, and a second pressure sensor.

15. A display device comprising a flexible circuit board, an integrated circuit chip, and a display panel, wherein the display panel comprises a display area and a terminal area, the terminal area comprises a first terminal area, a second terminal area, and a wiring area, and the wiring area is located between the first terminal area and the second terminal area; and
wherein the display area, the first terminal area, the wiring area, and the second terminal area are arranged sequentially in a first direction, and a length of the wiring area in the first direction is 50 μm-200 μm; or
wherein the number of the second terminal areas and the number of the wiring areas are both two, the display area and the first terminal area are arranged in the first direction, one of the second terminal areas, one of the wiring areas, the first terminal area, the other of the wiring areas, the other of the second terminal areas are sequentially arranged in a second direction, and lengths of both of the wiring areas in the second direction are both 50 μm-400 μm.

16. The display device according to claim 15, wherein the display area, the first terminal area, the wiring area, and the second terminal area are sequentially arranged in the first direction, and the length of the wiring area in the first direction is 100 μm-200 μm.

17. The display device according to claim 15, wherein the lengths of both of the wiring areas in the second direction are both 100 μm-400 μm.

18. The display device according to claim 15, wherein the first direction is perpendicular to the second direction.

19. The display device according to claim 15, wherein both of the wiring areas have a same length in the second direction, and/or both of the wiring areas have a same length in the first direction.

20. The display device according to claim 19, wherein both of the second terminal areas are symmetrically arranged on opposite sides of the first terminal area, and both of the wiring areas are symmetrically arranged on the opposite sides of the first terminal area.
